(19) United States
(12) Patent Application Publication
(10) Pub. No.: US 2025/0201552 A1
(43) Pub. Date: Jun. 19, 2025

(54) ELECTROMAGNETIC WAVE ASSISTED AREA SELECTIVE DEPOSITION

(71) Applicant: International Business Machines Corporation, Armonk, NY (US)

(72) Inventors: Krystelle Lionti, San Jose, CA (US); Aakash Pushp, Santa Clara, CA (US); Rudy J. Wojtecki, San Jose, CA (US); Noel Arellano, Gilroy, CA (US); Ronald R. Labby, San Jose, CA (US); Slavko N. Rebec, San Jose, CA (US)

(21) Appl. No.: 18/541,364

(22) Filed: Dec. 15, 2023

(51) Int. Cl. H01L 21/02; H01L 21/027

(52) U.S. Cl. CPC H01L 21/02345; H01L 21/0228; H01L 21/0274

(57) ABSTRACT

Provide an initial structure including a substrate; a plurality of spaced-apart metal lines, outward of the substrate; and a plurality of dielectric regions, outward of the substrate, and between the plurality of spaced-apart metal lines. Apply a reactive material of interest on an outer surface of the initial structure to produce a secondary structure. Apply electromagnetic radiation, such as microwaves, to the secondary structure to cause development of an electric field adjacent the plurality of dielectric regions, but not adjacent the plurality of spaced-apart metal lines, which in turn causes reaction of the reactive material of interest adjacent the plurality of dielectric regions, but not adjacent the plurality of spaced-apart metal lines. This produces a tertiary structure with unreacted reactive material of interest adjacent the plurality of spaced-apart metal lines and reacted reactive material of interest adjacent the plurality of dielectric regions.

### BACKGROUND

The present invention relates generally to the electrical, electronic and computer arts and, more particularly, to deposition techniques for semiconductor fabrication and the like.

Area selective deposition (ASD) is a technique for material deposition where material is deposited only on desired areas of a substrate. In a prior art approach, inhibitors are employed to achieve ASD on metal-dielectric patterns. These techniques begin with a structure including a dielectric, such as SiCOH ultra-low-K dielectric, with copper lines located between dielectric regions. An inhibitor is deposited, which selectively attaches to the copper. Then, additional dielectric is deposited. The additional dielectric adheres everywhere except where the inhibitor is located. When the inhibitor is removed, a structure is obtained including a dielectric, such as SiCOH ultra-low-K dielectric, with copper lines located between dielectric regions, and with the deposited additional dielectric over the dielectric from the original structure, but not over the copper. This structure can be obtained without having to use traditional lithography processes.

### BRIEF SUMMARY

Principles of the invention provide techniques for electromagnetic wave assisted area selective deposition. In one aspect, an exemplary method includes providing an initial structure, which includes a substrate; a plurality of spaced-apart metal lines, outward of the substrate; and a plurality of dielectric regions, outward of the substrate, and between the plurality of spaced-apart metal lines. A further step includes applying a reactive material of interest on an outer surface of the initial structure to produce a secondary structure. A still further step includes applying electromagnetic radiation to the secondary structure to cause development of an electric field adjacent the plurality of dielectric regions, but not adjacent the plurality of spaced-apart metal lines. This in turn causes reaction of the reactive material of interest adjacent the plurality of dielectric regions, but not adjacent the plurality of spaced-apart metal lines, to produce a tertiary structure with unreacted reactive material of interest adjacent the plurality of spaced-apart metal lines and reacted reactive material of interest adjacent the plurality of dielectric regions.

In another aspect, another exemplary method includes providing an initial structure, which includes a substrate; a plurality of spaced-apart metal lines, outward of the substrate; and a plurality of dielectric regions, outward of the substrate, and between the plurality of spaced-apart metal lines. A further step includes carrying out a vapor deposition process while applying electromagnetic radiation to the initial structure to cause an electric field adjacent the plurality of dielectric regions, but not adjacent the plurality of spaced-apart metal lines, so that a vapor phase precursor forms a film adjacent the plurality of dielectric regions, but not adjacent the plurality of spaced-apart metal lines.

In still a further aspect, an exemplary apparatus includes a vacuum chamber; a workpiece holder disposed within the vacuum chamber; a precursor source disposed in communication with the vacuum chamber; and an electromagnetic wave source disposed in relation to the vapor chamber to irradiate a workpiece held in the workpiece holder while the precursor source is active.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-4 show exemplary steps in an exemplary method, according to an aspect of the invention;

FIGS. 5 and 6 show exemplary steps in another exemplary method, using an apparatus according to an aspect of the invention;

FIGS. 7 and 8 show aspects of an electric field, according to an aspect of the invention;

FIGS. 9-16 show alternating atomic force microscope (AFM) images (FIGS. 9, 11, 13, and 15) and height plots (FIGS. 10, 12, 14, and 16) for an example application of the process of FIGS. 1-4;

FIG. 17 is a scanning electron microscopy (SEM) cross section showing results of an example application of the process of FIGS. 1-4;

FIGS. 18-21 show alternating atomic force microscope (AFM) images (FIGS. 18 and 20) and height plots (FIGS. 19 and 21) for another example application of the process of FIGS. 1-4; and

FIGS. 22 and 23 are scanning electron microscopy (SEM) cross sections showing results of the other example application of the process of FIGS. 1-4.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

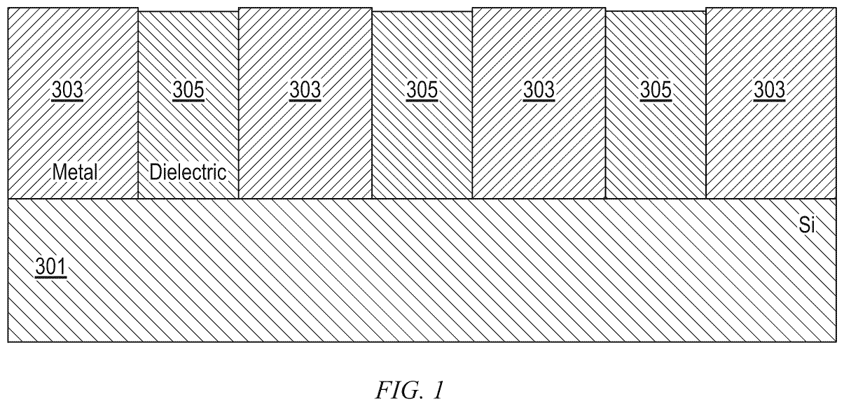

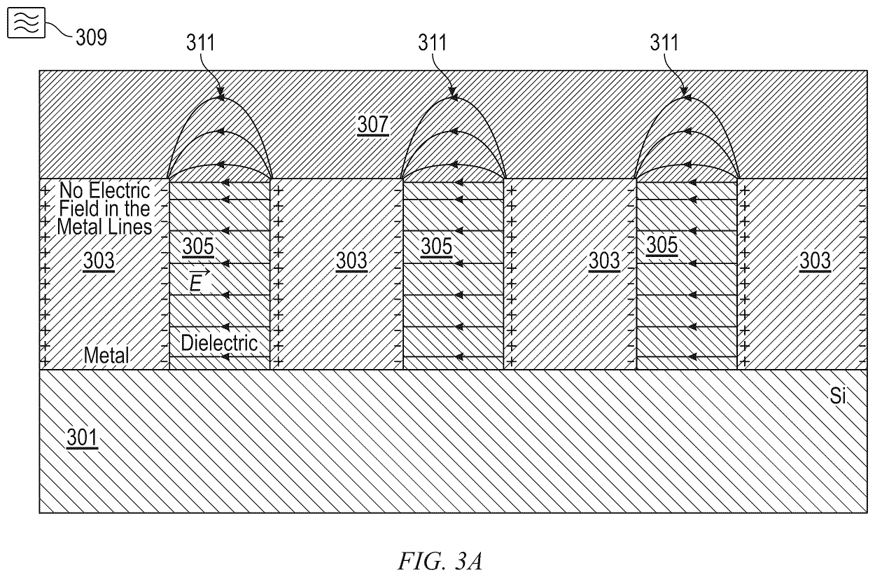

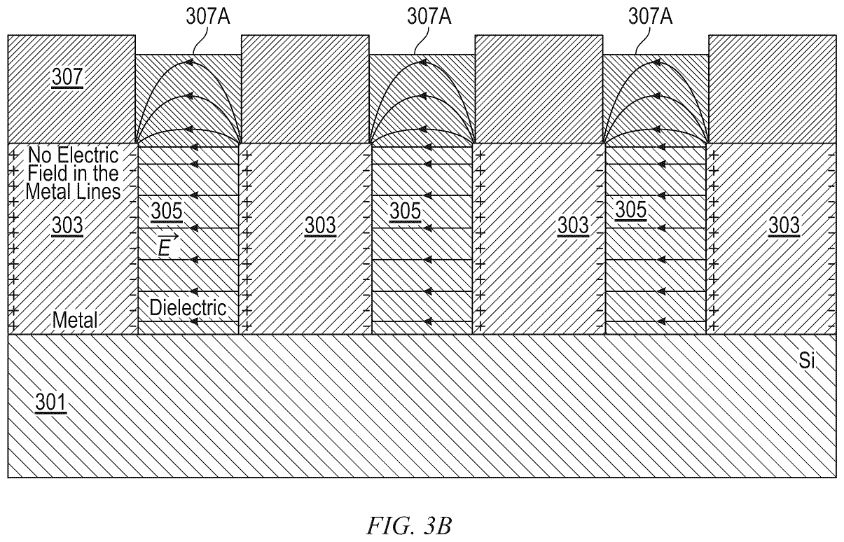

Given the discussion herein (reference characters refer to the drawings discussed below), and referring to FIGS. 1-4, it will be appreciated that an exemplary method includes providing an initial structure. The initial structure includes a substrate 301; a plurality of spaced-apart metal lines 303, outward of the substrate; and a plurality of dielectric regions 305, outward of the substrate, and between the plurality of spaced-apart metal lines. A further step includes applying a reactive material of interest 307 on an outer surface of the initial structure to produce a secondary structure (the material is reactive in the sense that it reacts to electromagnetic radiation). A further step includes applying electromagnetic radiation, as seen at 309, to the secondary structure to cause development of an electric field 311 adjacent the plurality of dielectric regions, but not adjacent the plurality of spaced-apart metal lines, which in turn causes reaction of the reactive material of interest adjacent the plurality of dielectric regions, but not adjacent the plurality of spaced-apart metal lines, to produce a tertiary structure seen in FIG. 3B, with unreacted reactive material of interest 307 adjacent the plurality of spaced-apart metal lines and reacted reactive material of interest 307A adjacent the plurality of dielectric regions. This provides the benefit of the ability to deposit 1-100 nm thick, self-aligned material of interest (MOI) in a selective manner.

In some cases, applying the electromagnetic radiation includes applying microwaves. This provides the benefit of selective deposition using microwave sources.

In one or more embodiments, applying the electromagnetic radiation includes carrying out at least one of controlling radiation intensity and controlling radiation duration so that an average bulk temperature of the secondary structure and an average bulk temperature of the tertiary structure do not exceed 500° C., or even 275° C., or even 150° C. This provides the benefit of near-instantaneous process employing electromagnetic wave durations on the nanosecond (ns) to second(s) scale.

One or more embodiments further include carrying out a finite element analysis to determine at least one of the radiation intensity and the radiation duration; the applying of the electromagnetic radiation is then carried out in accordance with the finite element analysis. This provides the benefit of adapting known finite element techniques to accurately predict intensity and/or duration.

One or more embodiments further include treating the tertiary structure to remove the unreacted reactive material of interest. The reactive material of interest can be, for example, photoresist and the treating can be, for example, developing and rinsing. This provides the benefit of enabling further processing.

Applying the electromagnetic radiation can include carrying out the at least one of the controlling of the radiation intensity and the controlling of the radiation duration so that a local temperature of the photoresist does not exceed its glass transition temperature. This provides the benefit of protecting the photoresist.

In some instances, as depicted, the photoresist is negative tone photoresist; however, other embodiments can employ positive tone photoresist. This provides the benefit of processing using commonly available photoresists.

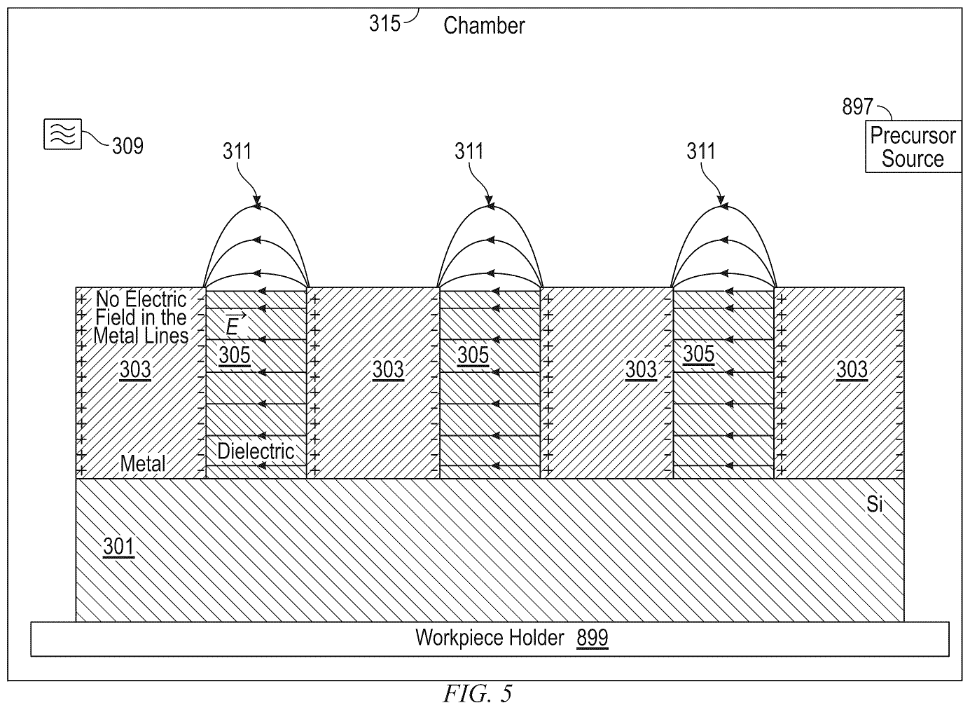

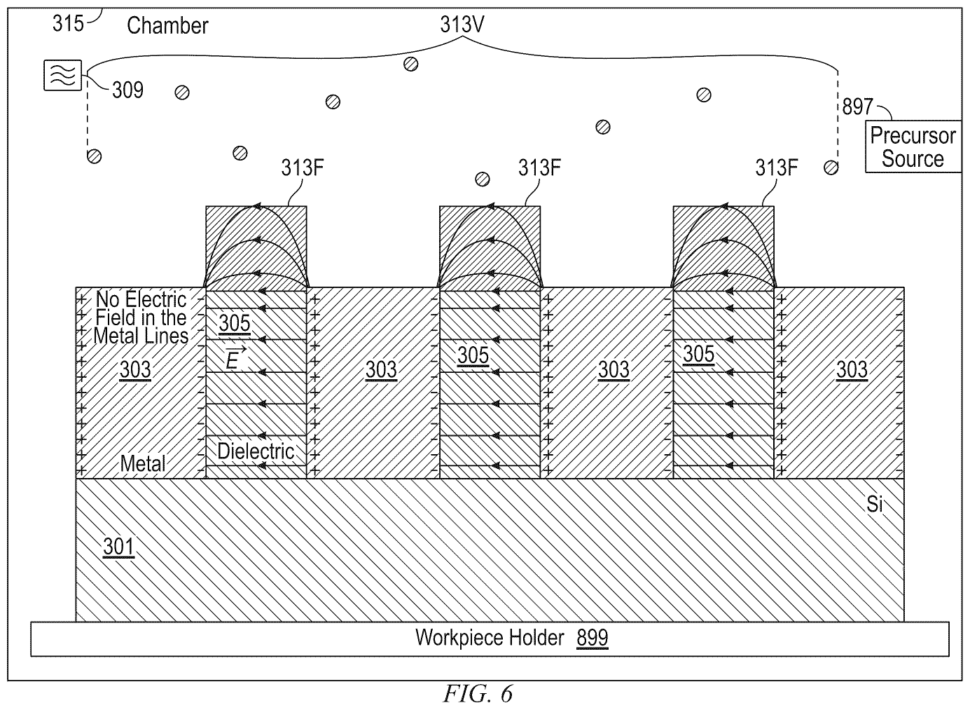

Furthermore, given the discussion thus far, referring to FIGS. 5-6, it will be appreciated that another exemplary method includes providing an initial structure; the initial structure includes a substrate 301; a plurality of spaced-apart metal lines 303, outward of the substrate; and a plurality of dielectric regions 305, outward of the substrate, and between the plurality of spaced-apart metal lines. A further step includes carrying out a vapor deposition process while applying electromagnetic radiation to the initial structure to cause an electric field 311 adjacent the plurality of dielectric regions, but not adjacent the plurality of spaced-apart metal lines, so that a vapor phase precursor forms a film adjacent the plurality of dielectric regions, but not adjacent the plurality of spaced-apart metal lines. In this context, “while” means that the deposition and electromagnetic waves application overlap for at least some period of time but they can be started together or either one can start before the other. This provides the benefit of the ability to deposit 1-100 nm thick, self-aligned material of interest (MOI) in a selective manner.

In one or more embodiments, applying the electromagnetic radiation includes applying microwaves. This provides the benefit of selective deposition using microwave sources.

Applying the electromagnetic radiation can include carrying out at least one of controlling radiation intensity and controlling radiation duration so that an average bulk temperature of the initial structure does not exceed 500° C., or even 275° C., or even 150° C. This provides the benefit of near-instantaneous process employing electromagnetic wave durations on the nanosecond (ns) to second(s) scale.

One or more embodiments further include carrying out a finite element analysis to determine at least one of the radiation intensity and the radiation duration; the applying of the electromagnetic radiation is then carried out in accordance with the finite element analysis. This provides the benefit of adapting known finite element techniques to accurately predict intensity and/or duration.

The vapor deposition process can be ALD or CVD, for example. The skilled artisan will appreciate that ALD precursors are known to be quite polar and will respond to the electric field. The described structure is introduced into the tool chamber in one or more embodiments. This provides the benefit of modifying known tools in accordance with aspects of the invention to carry out selective deposition.

For one or more embodiments, including both FIGS. 1-4 and FIGS. 5-6, further conventional processing can be carried out, including depositing a subsequent material of interest. When used for back-end-of-line (BEOL) wiring that connects to a device layer (e.g., field effect transistors such as nanosheet field effect transistors) using vias, the starting structure can include the devices and vias that connect to the metal lines. This provides the benefit of using aspects of the invention to fabricate a variety of circuits.

Even further, given the discussion thus far, referring to FIGS. 5-6, it will be appreciated that an exemplary apparatus includes a vacuum chamber 315; a workpiece holder 899 (e.g., stage) disposed within the vacuum chamber; a precursor source 897 disposed in communication with the vacuum chamber; and an electromagnetic wave source 309 (for example, a microwave source) disposed in relation to the vapor chamber to irradiate a workpiece held in the workpiece holder while the precursor source is active. Other than the wave source, the tool can be a conventional ALD or CVD tool. One or more embodiments include a controller (e.g., programmed microprocessor, digital microcontroller) to control radiation intensity/duration, introduction of precursor(s), etc. This provides the benefit of modifying known tools in accordance with aspects of the invention to carry out selective deposition.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:

Ability to deposit 1-100 nm thick, self-aligned material of interest (MOI) in a selective manner

A near-instantaneous process employing electromagnetic wave durations on the nanosecond (ns) to second(s) scale A one-step, direct-writing, area selective deposition approach on metal-dielectric patterns.

One or more embodiments provide area selective deposition techniques that do not need an inhibitor. We have found that application of electromagnetic waves (microwaves are a non-limiting example) to a metal-dielectric pattern will readily create a localized undulating electric field/energy profile inside and outside the pattern. In particular, the electric field inside the metal is zero (by definition), and consequently, the electric field is concentrated in the material that is in between the metal lines (i.e., in the dielectric, as well as the region atop the dielectric). A strong enough electric field can subsequently trigger chemical reaction/material transformation in a localized manner. This can be implemented in many different ways; two non-limiting examples of process flow are set forth below.

Microwaves include electromagnetic energy at the lower frequency end of the electromagnetic spectrum (0.3-300 GHz), and are a non-limiting example of electromagnetic waves. Within this region, only molecular rotation is affected, not the molecular structure. A frequency of 2.45 GHz is preferred in one or more non-limiting exemplary embodiments because it is readily available and has an appropriate penetration depth to interact with a sample. Electromagnetic wave energy includes an electric field and a mutually perpendicular magnetic field, though primarily only the electric field transfers energy to heat a substance. Electromagnetic waves couple instantly and directly with molecules in a specimen (unlike conductive heat where the vessel holding the specimen needs to heat first). Any material that will react to either dipole rotation or ionic conduction will instantly and locally start heating. Advantageously, electromagnetic waves exhibit an “instant on-instant off” property such that when the electromagnetic wave energy is turned off, the heat that resulted from the waves is all that remains, and it dissipates into the environment over time. Electromagnetic waves can be provided to a sample, for example, through a vessel wall that is transparent to electromagnetic wave energy.

As will be appreciated by the skilled artisan, in a positive tone resist, the resist is exposed where the underlying material is to be removed; the exposure changes the resist so that it becomes more soluble in the developer. The exposed resist is then washed away leaving regions of the underlying material. Negative tone resists behave in the opposite manner; when exposed, the negative resist becomes more difficult to dissolve in developer, and therefore remains on the surface after exposure—the developer solution removes only the unexposed areas.

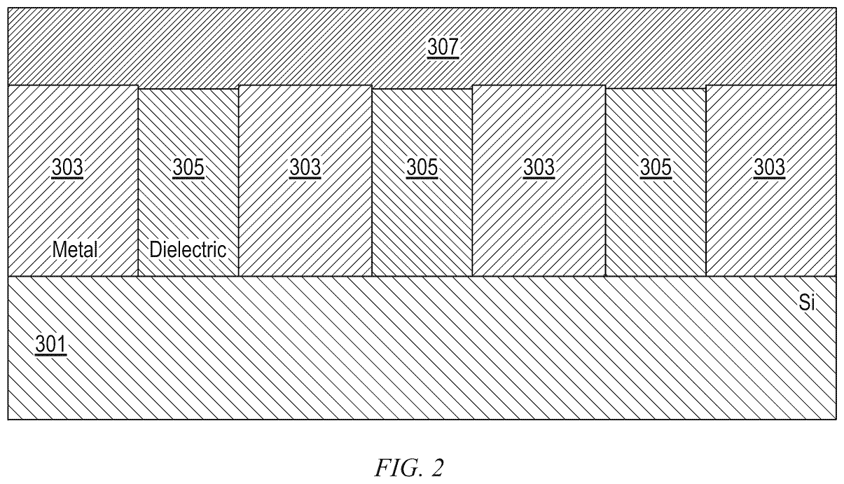

For a first exemplary process flow consider FIGS. 1-4, which uses a liquid photoresist. The schematics of FIGS. 1-4 are based on negative tone photoresist; the opposite tone could be obtained with positive tone photoresist. Given the teachings herein, the skilled artisan can apply positive or negative tone resist to implement one or more embodiments. In FIG. 1, begin with a structure including a substrate 301 (e.g., silicon); metal lines 303 (e.g., copper); and dielectric 305, such as SiCOH ultra-low-K dielectric (K=dielectric constant). The metal lines are located between the dielectric regions, and the metal lines and dielectric are atop the substrate. A surface cleaning operation can be formed, as appropriate. In FIG. 2, deposit a material of interest (MOI) 307, such as a reactive material of interest (e.g., photoresist). This can be done, for example, by spin-coating of reactive material of interest (MOI) on the patterned substrate (i.e., the substrate 301 with alternating dielectric 305 and metal 303 on top).

In FIG. 3A, apply electromagnetic radiation symbolized by waveforms 309. By definition, no electric field exists in metals (they reflect electromagnetic waves). Because of the initial patterning, an electric field is only present in between metal 303, inside of the dielectric material 305. The electric field lines can be seen at 311. They are very strong in the deposited photoresist 307, but only in the regions of the photoresist 307 that are on top of the dielectric material 305, whereas the electric field lines are weaker in the regions of the deposited photoresist on top of the metal lines. If the electric field is applied for only a short amount of time, it will directly and instantaneously heat the photoresist material only in the regions on top of the dielectric 305, and not so much, or not at all, on top of the metal lines 303. Note that conductive heating by the virtue of the metal lines heating up from the electromagnetic wave energy first and thereafter transferring the heat to the deposited photoresist is still possible. The portions of the photoresist material 307 that are located over the metal lines have little or no electric field, and therefore they do not heat instantaneously, and thus do not react. Thus, in FIG. 3A, apply electromagnetic radiation, leading to undulation in the electric field/energy profile in the MOI 307 interfaced with the pattern. The MOI near the dielectric top surface couples more strongly with the electromagnetic waves (compared to the MOI near the metal top surface). We have found that, with appropriate electromagnetic wave power and time settings, localized chemical reaction/transformation of the MOI 307 on top of the dielectric occurs, creating a large enough contrast in reaction between the MOI on top of the dielectric and that on top of the metal. FIG. 3B shows the structure of FIG. 3A with reacted MOI designated as 307A.

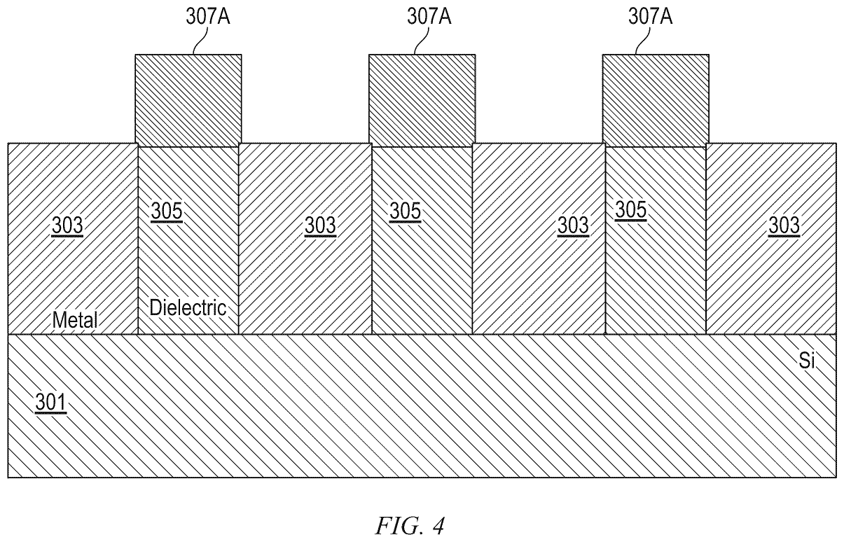

As shown in FIG. 4, this photoresist material that has not reacted can be removed (i.e., only the material that is on top of the copper lines). The reacted material 307A over the dielectric remains. Thus, in FIG. 4, develop/rinse off unreacted MOI (essentially, dissolving unreacted material of interest).

The first exemplary process flow can thus be summarized as deposition/growth of a blanket film including a reactive material of interest, over a conductor (metal)-dielectric pattern of interest, as in FIG. 2; applying electromagnetic waves to this pattern, thereby creating a well-defined electric field in the dielectric and the region atop the dielectric but not in the metal and reacting the material of interest subject to the electric field, as in FIGS. 3A and 3B; and, if needed, developing and rinsing the reacted or unreacted (depending on the tone of the resist) material of interest, as in FIG. 4. Thus, FIGS. 1-4 depict a electromagnetic wave-assisted ASD (liquid-based process).

We have performed experiments and simulations that are discussed further elsewhere herein.

For a second exemplary process flow, consider FIGS. 5 and 6. The schematics of FIGS. 5 and 6 are based on negative tone resist; the opposite tone could be obtained with positive tone resist. Given the teachings herein, the skilled artisan can apply positive or negative tone resist to implement one or more embodiments. This exemplary flow is based on an all integrated vapor-phase process, instead of working with liquid photoresist material. Begin with the structure of FIG. 5, which is similar to that of FIG. 1, and apply electromagnetic radiation symbolized by waveforms 309 causing the electric field whose electric field lines can be seen at 311. In the exemplary flow of FIGS. 5 and 6, this is done without photoresist material. Thus, in FIG. 5, apply electromagnetic waves, leading to undulation in the electric field/energy profile at the pattern surface. This can be done while the sample is in a chamber 315 as discussed below.

In FIG. 6, start the film growth process by introducing the vapor phase precursor inside the chamber 315 of a suitable machine (e.g., atomic layer deposition (ALD) machine, chemical vapor deposition (CVD) machine, or the like). The vapor phase precursor in the vapor phase is designated as 313V. This starts film growth, which occurs via selective reaction where the electric field is present, resulting in film 313F. The electric field lines are not labeled in FIG. 6 to avoid clutter. When electromagnetic wave power and time are adjusted appropriately, the ALD/CVD reactants near the dielectric top surface couple more strongly with the electromagnetic waves (compared to the reactants near the metal top surface), leading to localized chemical reactions on top of the dielectric. Referring to 313F in FIG. 6, because of the electric field lines, strongest on top of the dielectric material, vapor phase material is only deposited there. It should be noted that in one or more embodiments, ALD or CVD is carried out while applying electromagnetic waves.

The second exemplary process flow can thus be summarized as applying electromagnetic waves to a conductor (metal)-dielectric pattern, thereby creating a well-defined electric field in the dielectric and the region atop the dielectric but not in the metal, as in FIG. 5; and using the electric field to locally grow a film (e.g. by ALD), as in FIG. 6. Between FIG. 5 and FIG. 6, a precursor 313V is introduced. In FIG. 6, start film growth (ALD, CVD, or the like), which is based on selective reaction where the electric field is present.

Thus, FIGS. 5 and 6 depict a electromagnetic wave-assisted ASD (all integrated vapor phase process).

In at least some aspects, vapor phase processes may be preferred to liquid phase. One or more embodiments are particularly advantageous for small feature sizes. Alignment is a significant issue at small feature sizes. For example, for 200 nm wide copper lines, one could, in principle, carry out a patterning step. However, if 20 nm wide copper lines are desired, alignment will be challenging. Advantageously, in one or more embodiments, the use of electromagnetic waves to induce local chemical reaction results in a self-aligned system. Self-alignment relates to both liquid and vapor phase aspects.

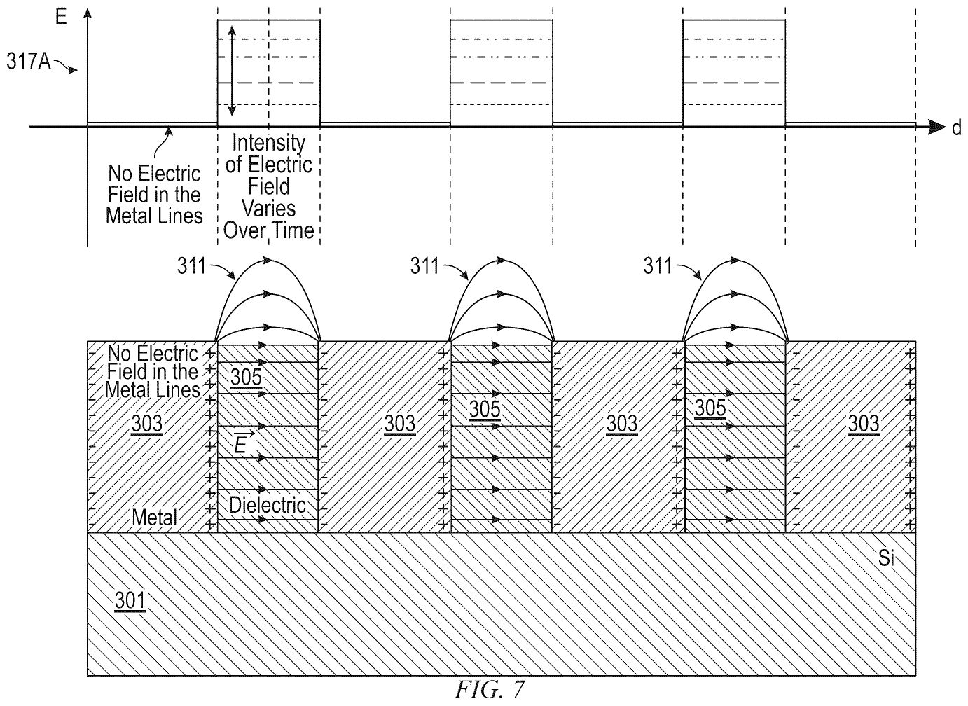

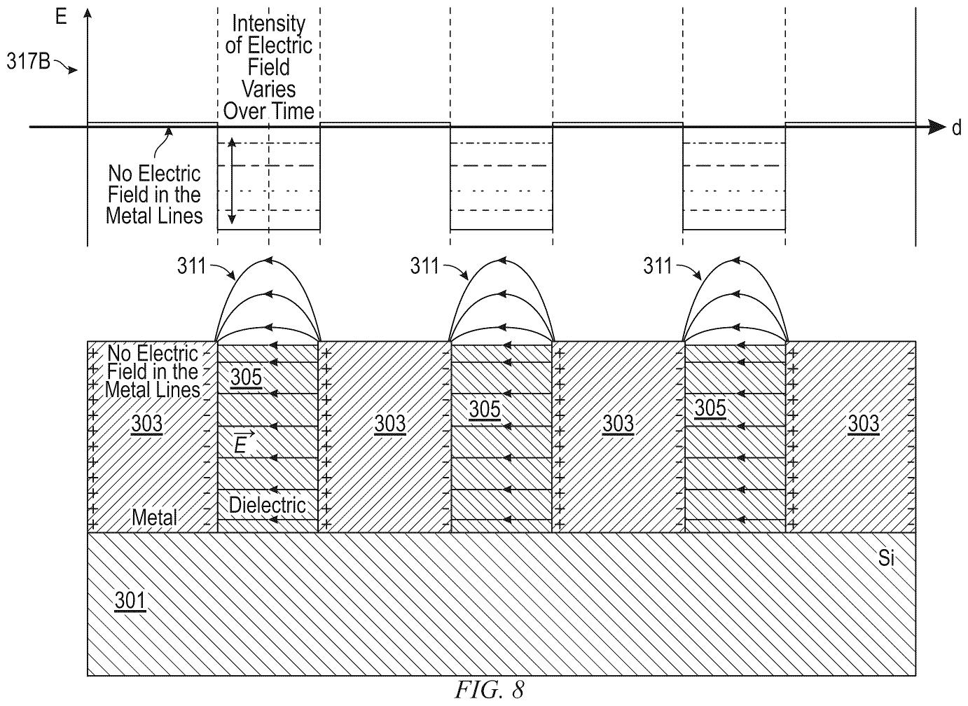

Refer now to FIGS. 7 and 8 for illustrations of additional aspects of the electromagnetic wave-induced electric fields (electromagnetic waves applied on line-space patterns). FIGS. 7 and 8 are generally similar to FIG. 3 (without the photoresist material 307) and to FIG. 5. FIG. 7 shows the electric field lines 311 oriented with − on the right and + on the left, while FIG. 8 shows the electric field lines 311 oriented with + on the right and − on the left as in FIGS. 3A-5. Note the corresponding plots 317A, 317B of the electric field, showing that there is no electric field in the metal lines 303 while the intensity of the electric field over the dielectric 305 varies over time. The different line characteristics symbolize the electric field intensities at different times.

As noted, by definition, no electric field exists in metals (they reflect electromagnetic waves). However, free electrons (e⁻) in the metal move around and follow the electromagnetic wave electric field. In turn, the electric field lines are modified and strengthened in the dielectric in between the metal lines. The electric field lines are also “pretty strong” on top of the dielectric itself (i.e., relative to the surface atop the metal). When applied on a metal-dielectric pattern, the electric field is primarily concentrated in between the metal lines (i.e. in the dielectric, as well as in the region atop the dielectric). The application of electromagnetic waves to a metal-dielectric pattern will readily create a localized undulating electric field/energy profile inside and outside the dielectric material. A strong enough localized electric field can trigger localized chemical reaction/material transformation on top of the dielectric (while no measurable reaction takes place on top of the metal). In addition, electromagnetic waves whose frequency is resonant with the choice of ALD precursors for Area Selective Deposition (ASD) will advantageously have a larger effect on localized deposition atop the dielectric surface.

One or more embodiments advantageously operate in a regime where minimal heating of the patterned substrate occurs. This can be achieved by either reducing the energy/amplitude/power of the continuously applied electromagnetic wave, and/or by applying a periodic train of short pulses of the electromagnetic wave where the duty cycle doesn't allow appreciable heating of the sample. We have found that applying short electromagnetic wave pulses (with enough delay in between pulses) to the sample is one way to controllably deposit a precursor while preventing the system from excessively heating up.

We have carried out experimental simulations using finite element software (Ansys® HFSS 3D High Frequency Structure Simulation Software (registered mark of ANSYS, INC. CANONSBURG PENNSYLVANIA USA)). FIG. 24 depicts a 3-D model; the three “fingers” are metal (each being 100 nm wide and 100 nm tall and spaced apart by 100 nm) and the remainder is dielectric. The metal-dielectric pattern is located on top of a substrate (as in FIG. 1, for example). FIG. 25 shows a condition when the electromagnetic waves are turned on, inducing the electric field. The dark squares represent a cross section of the metal lines where there is no electric field. The electric field intensity is indicated in the bar at the right margin. The horizontal axis shows the horizontal distance “X” in microns and the vertical axis shows the vertical distance “Z” above the surface in microns.

FIG. 26 shows the relative electric field magnitude (vertical axis) versus the horizontal distance “X” in nanometers. The different plots show the electric field for various Z values as indicated. Below the surface of the metal, the electric field is zero. The electric field increases sharply outside the metal. The plots exhibit a V-shape, zero in the middle of the metal but climbing up to very high values. The electric field is quite high right on top of the dielectric (e.g., +1 nm) in between the metal lines and remains quite high up to about 100 nm above the dielectric determined by the dimensions of the metal lines. Note that for the −1 nm curve, wherever there is metal, the electric field is zero. Note the significant difference between the −1 nm curve and the +1 nm curve, which aids in self-alignment. Note that the kinks at the transition between metal and dielectric are artifacts of the simulation originating from sharp corners of the metal, which is a well-known issue in such finite element simulations due to meshing faults.

It is worth noting that ALD precursors are quite polar. They will strongly couple to the electric field thereby preferentially congregating in the high electric field regions. When the electromagnetic radiation is applied, the electrons in the metal will also respond, causing the metal to heat. However, one or more embodiments do not rely on conductive heating from the metal onto the precursor/photoresist-rather, one or more embodiments employ very short electromagnetic wave durations to deliberately avoid heating that would degrade the resist, ALD precursor, or the sample specimen. Consider, for example, application of a continuous electromagnetic wave where the amplitude has been sufficiently reduced such that the whole chip has only heated up to 40-50° C. in equilibrium. In such a case, none of the resist will “cook.” Still, however, the electric field will only be high on top of the dielectric. If precursors are introduced (see, e.g., vapor phase precursor introduction in FIG. 6), the precursors will only experience, for example, 40-50° C. on the metal. On top of the dielectric, the precursors are also experiencing 40-50° C., but because of the additional electric field there, they are strongly coupled, so local heat transfer on top of the dielectric, on a molecular level, will be very high. At the scale of individual molecules impacted by the electromagnetic field, the kinetic energy may be very high, corresponding theoretically to hundreds or thousands of degrees C. (recall that the temperature of a substance is related to the average kinetic energy of its particles). However, pertinently, on a macroscopic level, the average temperature is only 40-50° C.

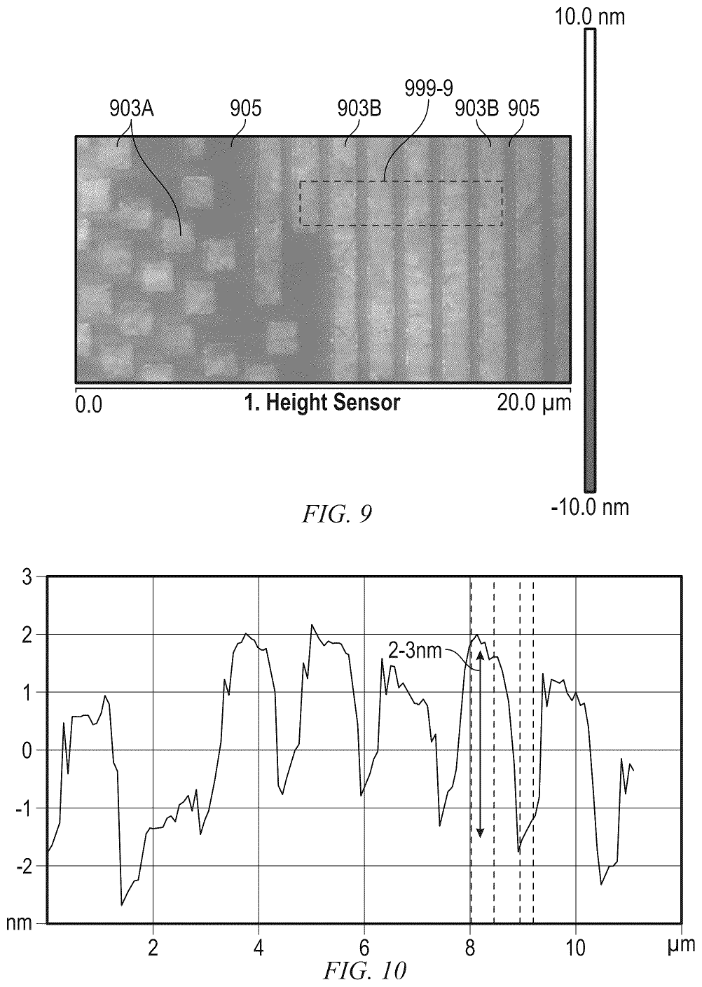

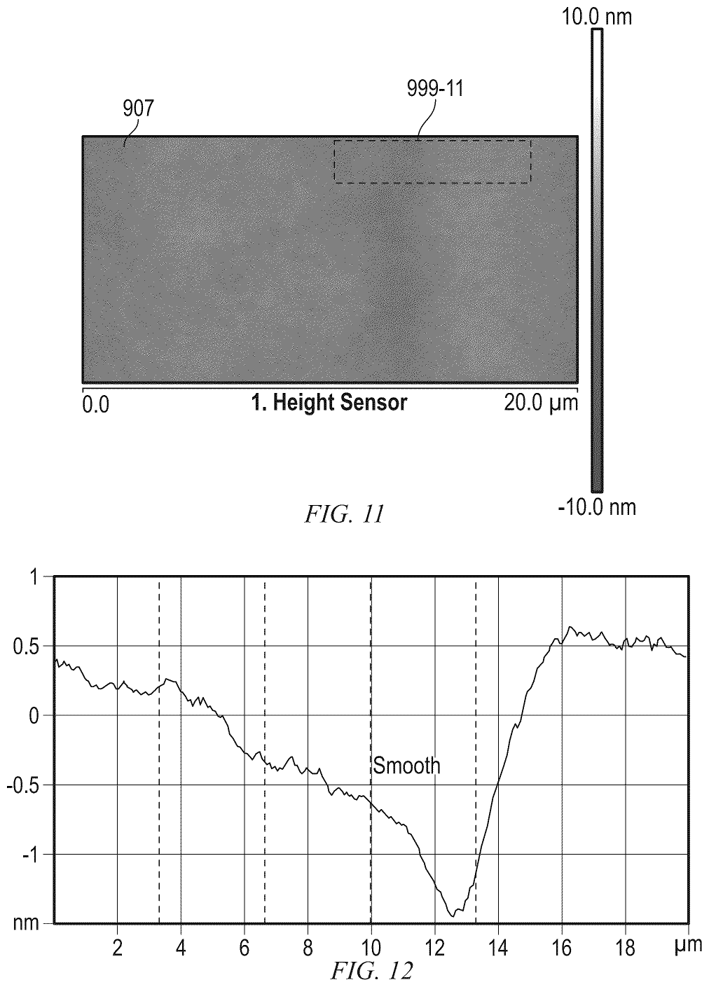

Example results will now be discussed with regard to applying the first exemplary process flow of FIGS. 1-4 to Cu (600 nm)-SiOₓ (300 nm) patterns, using N730 negative photoresist. Refer now to the atomic force microscope (AFM) image in FIG. 9. This starting pattern shows squares 903A and lines 903B made out of copper. Broadly, those are representative of metal features. In between is dielectric material 905. The lines and the dielectric material have a different appearance because of a slight difference in height; for example, 2-3 nanometers. FIG. 10 plots height versus lateral position in the dotted region 999-9 of FIG. 9 and shows the 2-3 nanometer height difference. FIG. 11 shows an AFM image of the structure of FIG. 9 after depositing photoresist 907 over the entire surface. In the non-limiting example in the figure, the thickness of the resist is 500 nanometers. As seen in FIG. 12, which plots height versus lateral position in the dotted region 999-11 of FIG. 11, after this resist deposition, the height difference on the featureless surface is only about 1 nanometer, and is accordingly labeled “smooth” (the scale on the vertical axis is very small, ranging from about-1.5 nm to +1 nm). Note that using the optical microscope of the AFM, the same location is being imaged with the AFM tip before and after deposition of the photoresist 907.

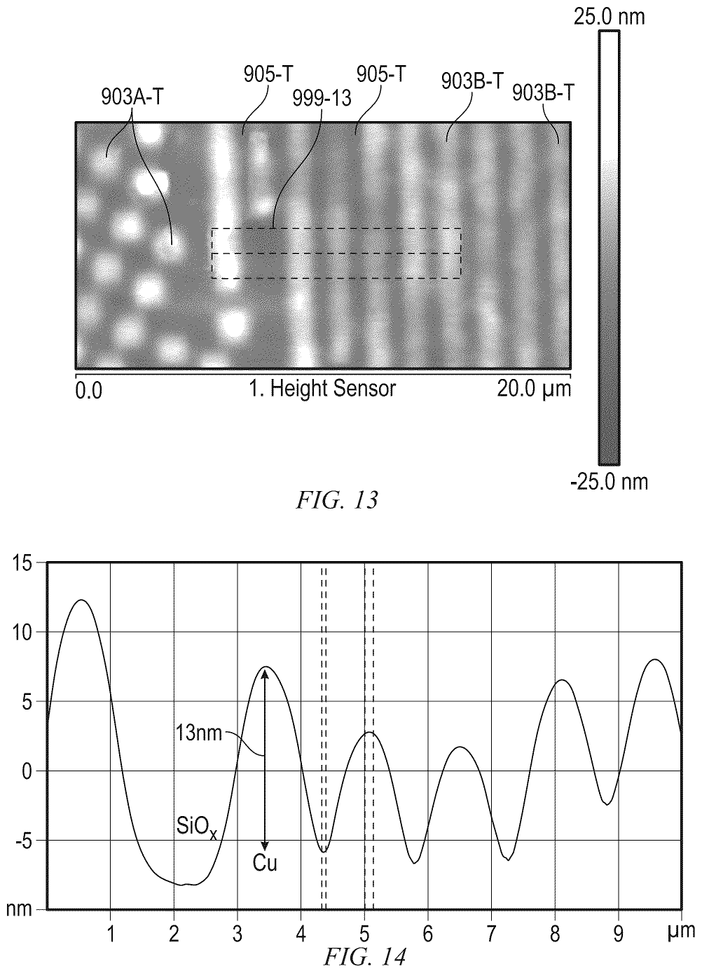

FIG. 13 shows the structure of FIG. 11 after application of electromagnetic waves; the features begin to become visible again; here, the height difference on the surface is about 13 nanometers. FIG. 14 plots height versus lateral position in the dotted region 999-13 of FIG. 13 and shows the approximately 13 nanometer height difference (the middle dotted line in 999-13 is the centerline of the relevant region). In FIG. 13, the photoresist on top of the dielectric has shrunk, but not the photo resist on top of the copper lines. This corresponds to FIG. 3B. The material 307A has reacted more as compared to the material 307 on top of the copper 303. The electromagnetic wave treatment reveals topography mirroring the initial pattern in FIG. 9. Additionally, the steps observed between the lines in FIG. 13 (about 13 nm) are larger than the initial ones (2-3 nm in FIG. 9). The resist material “densifies” more on top of the dielectric after the electromagnetic wave application. Note the pattern showing squares 903A-T and lines 903B-T over the features 903A and 903B and interspersed regions 905-T over 905.

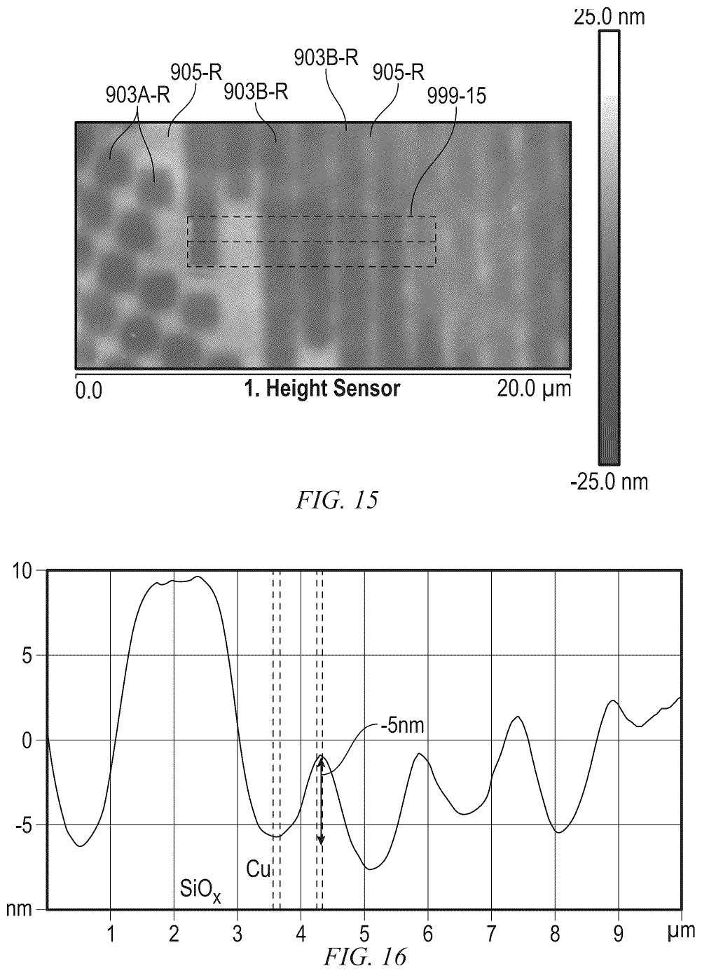

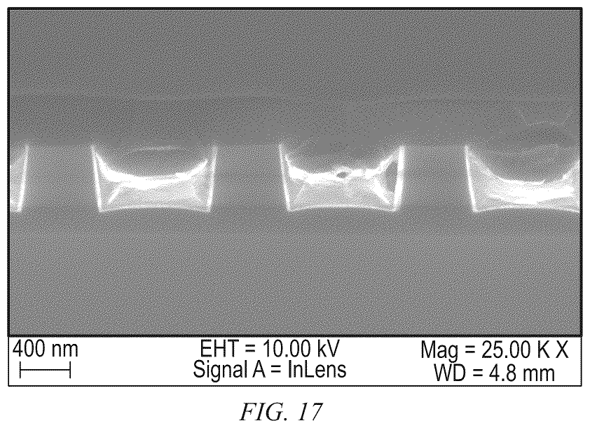

Referring to FIG. 15, this shrinking/reaction allows the photo resist to be developed in a selective manner. Note the tone reversal between FIGS. 13 and 15 (i.e., elements 903A-T, 903B-T, and 905-T respectively reverse to elements 903A-R, 903B-R, and 905-R). The unreacted photoresist is removed but the reacted photoresist is retained. This corresponds to FIG. 4. Here, the height difference has gone from 13 nanometers to −5 nanometers. FIG. 16 plots height versus lateral position in the dotted region 999-15 of FIG. 15 and shows the approximately −5 nanometer height difference. The middle dotted line in 999-15 is the centerline of the relevant region. Note, the height difference (delta Z) is measured between the copper line and the adjacent dielectric; thus, the possibility of a negative value. Again, between FIG. 13 and FIG. 15, note the reversal of the pattern. In FIG. 13, the lines 903B-T are light and the dielectric 905-T is dark; in FIG. 15, this reverses and the lines 903B-R are dark and the dielectric 905-R is light. Thus, following electromagnetic wave application, as seen in FIG. 15, the developer removes the least “densified” resist. Tone reversal is observed, with more resist going away on the metal than on the dielectric.

In experiments, we have been able to remove more of the photo resist on top of the copper. FIG. 17 is a scanning electron microscopy (SEM) cross section, and can be compared, for example, to FIG. 6. In FIG. 17, the photoresist is still present everywhere, but it is thinner on top of the copper. Given the teachings herein, the skilled person will understand that the bright regions in FIG. 17 are metal, with dielectric in between, silicon wafer underneath, and photoresist with undulations on top. These non-limiting experimental results were achieved with a standard kitchen microwave oven.

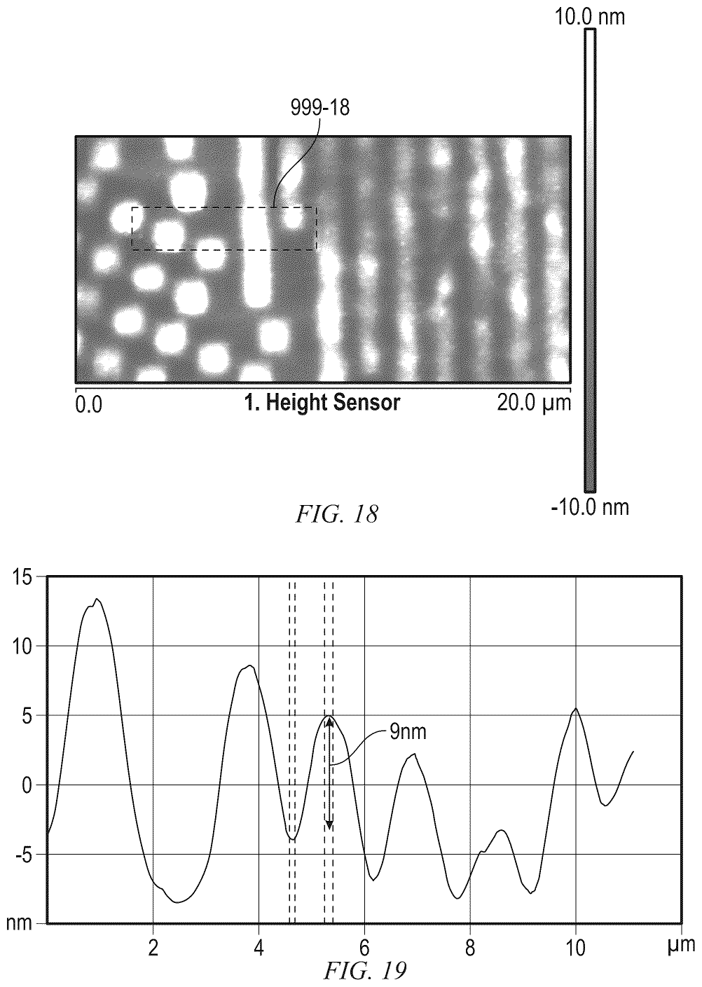

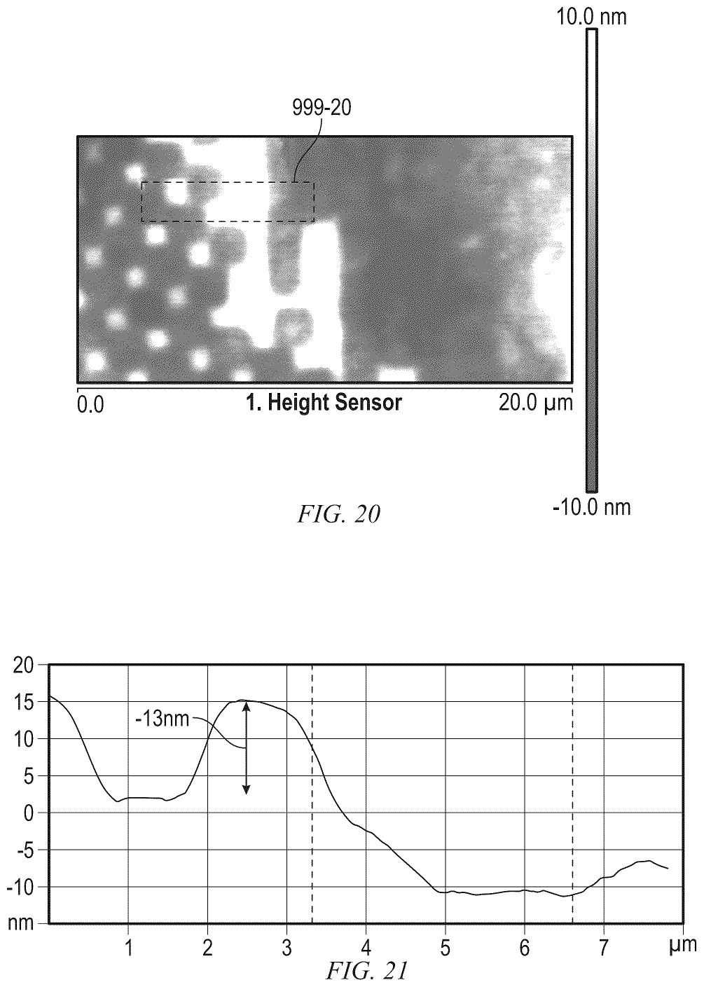

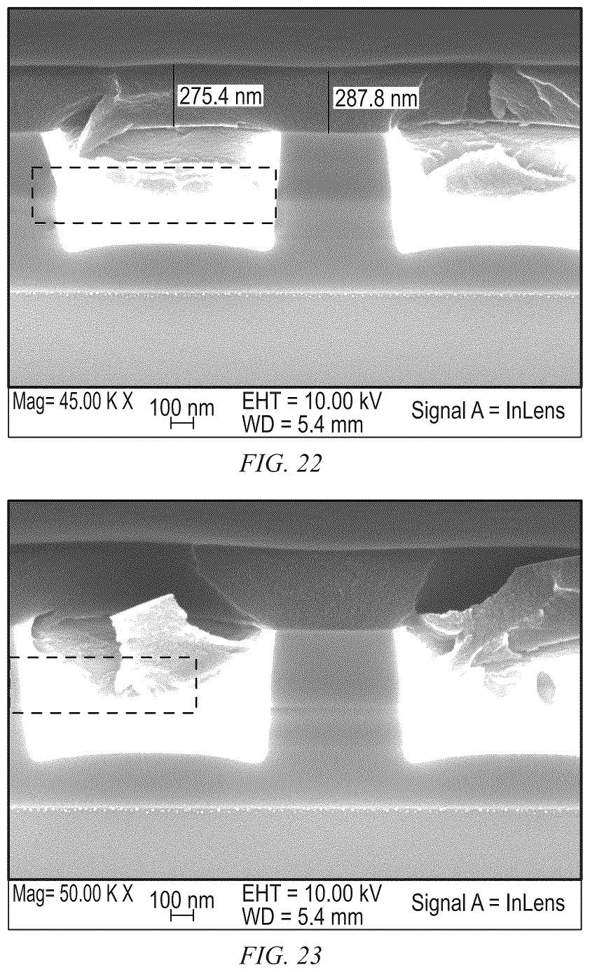

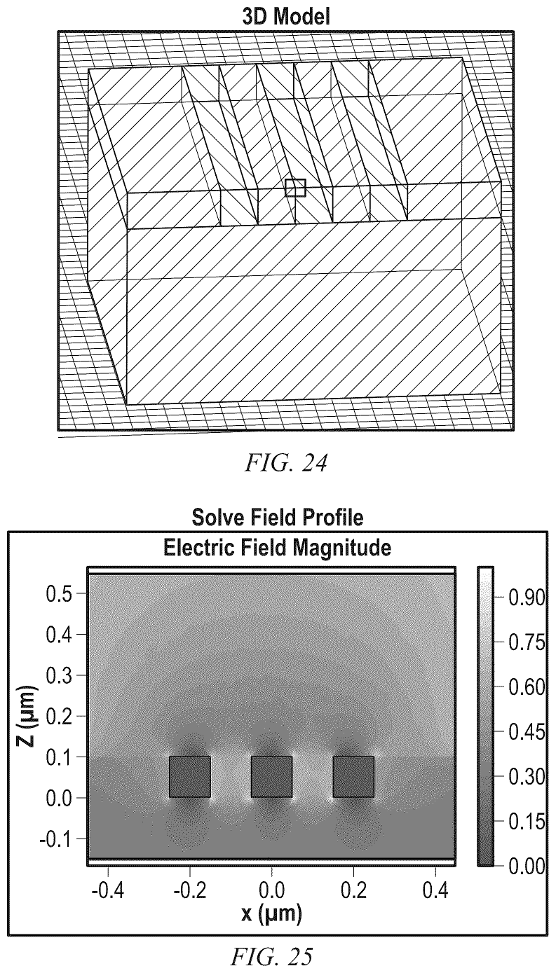

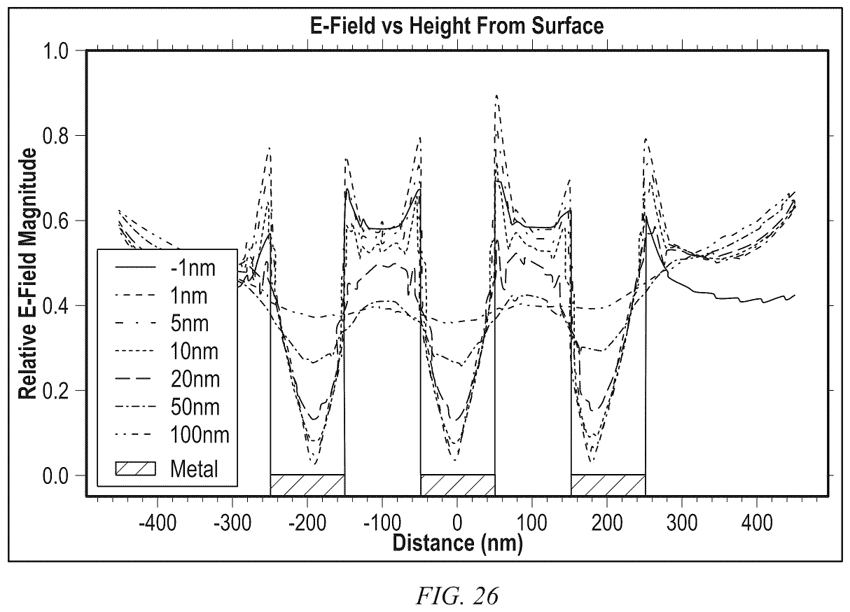

To demonstrate reproducibility, experiments were repeated. FIG. 18 shows a view similar to FIG. 13; namely, a sample after patterning, application of photoresist, and application of electromagnetic waves. FIG. 19 plots height versus lateral position in the dotted region 999-18 of FIG. 18 and shows the approximately 9 nanometer height difference. FIG. 20 shows the sample of FIG. 18 after development and is a view similar to FIG. 15. Note the tone reversal from FIG. 18. FIG. 21 plots height versus lateral position in the dotted region 999-20 of FIG. 20 and shows the approximately −5 nanometer height difference. Note that the lines, squares, and resist are not separately labeled in FIGS. 18 and 20 to avoid clutter. FIGS. 22 and 23 show corresponding SEM images.

In an example, 1000 Watts is applied for about 50-100 ms, waiting about 3 seconds between pulses for cooling. In an example, 1000 Watts is applied for 2 seconds without pulsing. Generally, better results would be anticipated with pulsing or with a lower wattage if there is no pulsing. Required wattage values are, of course, configuration-dependent, and could be determined by the skilled artisan from, for example, finite element analysis considering thermal and electromagnetic effects. Even better results can be anticipated with a more sophisticated electromagnetic wave device.

Thus, it should be noted that the electromagnetic wave amplitude and/or duration that is appropriate will vary based on the specific system including, for example, the number of layers of metallization. In one aspect, the electromagnetic wave amplitude and/or duration are controlled such that the temperature anywhere in the structure does not exceed 400 degrees C., or 275 degrees C., or 150 degrees C. The temperature in the photoresist could also be controlled to a certain value, in addition to and/or in lieu of controlling the overall temperature. Wattage values and other parameters needed to control, the temperature to a certain value are, of course, configuration-dependent, and could be determined by the skilled artisan from, for example, finite element analysis considering thermal and electromagnetic effects.

One or more embodiments are thus substantially different from prior art approaches where the goal of applying electromagnetic waves is to deliberately heat up metal sheets or to trigger chemical reactions through deliberate bulk conductive heating. In contrast, one or more embodiments are localized and selective. In one or more embodiments, while local heating of the dielectric is expected for short electromagnetic wave durations, this is unlike prior art approaches which deliberately rely on bulk conductive heating from the metal lines (e.g. copper). One or more embodiments instead rely on limited heating of the dielectric, without directly heating the metal. Indeed, one or more embodiments provide electromagnetic wave assisted localized deposition due to the localized electric field rather than deliberate bulk conductive heating. In one or more embodiments, the localized electric field on top of the dielectric surface in a metal-dielectric pattern affects localized chemistry without substantially raising the sample temperature (as noted above, in one or more embodiments, at the scale of individual molecules impacted by the electromagnetic field, the kinetic energy may be very high, corresponding theoretically to hundreds or thousands of degrees C. (recall that the temperature of a substance is related to the average kinetic energy of its particles). However, pertinently, on a macroscopic level, the average temperature is only, for example, 40-50° C.).

Given the teachings herein, for any elements for which example materials are not set forth, the skilled artisan can select appropriate materials, and for any fabrication steps for which specific exemplary processes have not been set forth, the skilled artisan can select appropriate known processes. One or more embodiments can be used wherever metal lines are desired, especially narrow (10 nm or less) self-aligned metal lines. Some embodiments can be used for back-end-of-line (BEOL) wiring that connects to a device layer (e.g., field effect transistors such as nanosheet field effect transistors) using vias. Exemplary known processes, in no particular order, include, for example, preparation (deposition/patterning) of nanosheet stacks with sacrificial SiGe regions, etch-back of sacrificial SiGe, formation of shallow trench isolation (STI), dummy gates including gate spacers, inner spacers, and dielectric isolation, dummy gate open, dummy gate removal, channel release, high-K metal gate (HKMG) stack deposition, self-aligned contact (SAC) cap and trench metal contact formation, and with lithography, masks, and patterning, generally. The skilled artisan will be familiar with the “dummy gate” process for forming HKMGs. More generally, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term.

Many different substrates can be used; non-limiting examples include bulk silicon, glass, sapphire, GaAs, and the like.

For any materials and processes not specifically called out, given the teachings herein, the skilled artisan can adapt standard techniques to implement one or more embodiments.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A method comprising:
providing an initial structure comprising:
a substrate;
a plurality of spaced-apart metal lines, outward of the substrate; and
a plurality of dielectric regions, outward of the substrate, and between the plurality of spaced-apart metal lines;
applying a reactive material of interest on an outer surface of the initial structure to produce a secondary structure;
applying electromagnetic radiation to the secondary structure to cause development of an electric field adjacent the plurality of dielectric regions, but not adjacent the plurality of spaced-apart metal lines, which in turn causes reaction of the reactive material of interest adjacent the plurality of dielectric regions, but not adjacent the plurality of spaced-apart metal lines, to produce a tertiary structure with unreacted reactive material of interest adjacent the plurality of spaced-apart metal lines and reacted reactive material of interest adjacent the plurality of dielectric regions.

2. The method of claim 1, wherein applying the electromagnetic radiation comprises applying microwaves.

3. The method of claim 2, wherein applying the electromagnetic radiation comprises carrying out at least one of controlling radiation intensity and controlling radiation duration so that an average bulk temperature of the secondary structure and an average bulk temperature of the tertiary structure do not exceed 500° C.

4. The method of claim 3, wherein applying the electromagnetic radiation comprises carrying out the at least one of the controlling of the radiation intensity and the controlling of the radiation duration so that the average bulk temperature of the secondary structure and the average bulk temperature of the tertiary structure do not exceed 275° C.

5. The method of claim 4, wherein applying the electromagnetic radiation comprises carrying out the at least one of the controlling of the radiation intensity and the controlling of the radiation duration so that the average bulk temperature of the secondary structure and the average bulk temperature of the tertiary structure do not exceed 150° C.

6. The method of claim 3, further comprising carrying out a finite element analysis to determine at least one of the radiation intensity and the radiation duration, wherein the applying of the electromagnetic radiation is carried out in accordance with the finite element analysis.

7. The method of claim 3, further comprising treating the tertiary structure to remove the unreacted reactive material of interest.

8. The method of claim 7, wherein the reactive material of interest comprises photoresist and the treating comprises developing and rinsing.

9. The method of claim 8, wherein applying the electromagnetic radiation comprises carrying out the at least one of the controlling of the radiation intensity and the controlling of the radiation duration so that a local temperature of the photoresist does not exceed its glass transition temperature.

10. The method of claim 9, wherein the photoresist comprises negative tone photoresist.

11. A method comprising:
providing an initial structure comprising:
a substrate;
a plurality of spaced-apart metal lines, outward of the substrate; and
a plurality of dielectric regions, outward of the substrate, and between the plurality of spaced-apart metal lines;
carrying out a vapor deposition process while applying electromagnetic radiation to the initial structure to cause an electric field adjacent the plurality of dielectric regions, but not adjacent the plurality of spaced-apart metal lines, so that a vapor phase precursor forms a film adjacent the plurality of dielectric regions, but not adjacent the plurality of spaced-apart metal lines.

12. The method of claim 11, wherein applying the electromagnetic radiation comprises applying microwaves.

13. The method of claim 12, wherein applying the electromagnetic radiation comprises carrying out at least one of controlling radiation intensity and controlling radiation duration so that an average bulk temperature of the initial structure does not exceed 500° C.

14. The method of claim 13, wherein applying the electromagnetic radiation comprises carrying out the at least one of the controlling of the radiation intensity and the controlling of the radiation duration so that the average bulk temperature of the initial structure does not exceed 275° C.

15. The method of claim 14, wherein applying the electromagnetic radiation comprises carrying out the at least one of the controlling of the radiation intensity and the controlling of the radiation duration so that the average bulk temperature of the initial structure does not exceed 150° C.

16. The method of claim 13, further comprising carrying out a finite element analysis to determine at least one of the radiation intensity and the radiation duration, wherein the applying of the electromagnetic radiation is carried out in accordance with the finite element analysis.

17. The method of claim 13, wherein carrying out the vapor deposition process comprises performing atomic layer deposition.

18. The method of claim 13, wherein carrying out the vapor deposition process comprises performing chemical vapor deposition.

19. An apparatus comprising:
a vacuum chamber;
a workpiece holder disposed within the vacuum chamber;
a precursor source disposed in communication with the vacuum chamber; and
an electromagnetic wave source disposed in relation to the vapor chamber to irradiate a workpiece held in the workpiece holder while the precursor source is active.

20. The apparatus of claim 19, wherein the electromagnetic wave source comprises a microwave source.
